(19) United States
(12) Patent Application Publication
(10) Pub. No.: US 2010/0164046 A1
(43) Pub. Date: Jul. 1, 2010

(54) IMAGE SENSOR AND METHOD FOR MANUFACTURING THE SAME

(76) Inventor: TAE GYU KIM, Gyeongsangnam-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/643,402

(22) Filed: Dec. 21, 2009

(30) Foreign Application Priority Data
Dec. 30, 2008 (KR) 10-2008-0136271

(51) Int. Cl. H01L 31/14; H01L 31/18

(52) U.S. Cl. 257/446; 438/73; 257/461; 257/466; 438/98; 257/E31.097

(57) ABSTRACT

An image sensor and a method for manufacturing the same are provided. The image sensor can include a semiconductor substrate, an interlayer dielectric, a second doped layer, a first doped layer, an ohmic contact layer, and metal contacts. The semiconductor substrate can have a pixel region and a peripheral region defined therein. The second doped layer, the first doped layer, and the ohmic contact layer can be stacked on the interlayer dielectric of the semiconductor substrate to form an image sensing device in the pixel region.

### CROSS-REFERENCE TO RELATED APPLICATION

This application claims the benefit under 35 U.S.C. §119 of Korean Patent Application No. 10-2008-0136271, filed Dec. 30, 2008, which is hereby incorporated by reference in its entirety.

### BACKGROUND

An image sensor is a semiconductor device that can convert optical images into electrical signals. Image sensors are generally classified as charge coupled devices (CCDs) or complementary metal oxide semiconductor (CMOS) image sensors (CIS).

CMOS image sensors typically have a structure in which a photodiode region converting optical signals into electrical signals and a transistor region processing the electrical signals are horizontally disposed.

In the horizontal type image sensor, since the photodiode region and the transistor region are horizontally disposed in a semiconductor substrate, there is a limitation in expanding an optical sensing part (referred to as “fill factor”) within a limited area.

As an alternative to overcome this limitation, attempts of forming a photodiode using amorphous silicon (Si), or forming a circuitry in a silicon (Si) substrate and forming a photodiode over the circuitry using a wafer-to-wafer bonding method have been made (hereinafter, referred to as a “three-dimensional (3D) image sensor). The photodiode is connected to the circuitry through a metal interconnection. Also, the photodiode has a stacked structure of an N-type layer and a P-type layer.

In an implementation of the 3D image sensor, a metal plug is formed to be connected to an N-type layer of a wafer in which a photodiode is formed and an interconnections in a deep via hole is formed in the photodiode.

However, the method for forming the metal plug requires a complicated process of removing a certain region of a metal layer to be selectively connected to the N-type layer after the metal layer is deposited in the deep via hole.

Also, there is a limitation in that the surface of a photodiode may be exposed due to a loss of a mask when an insulating layer in which a photodiode and an interconnection are formed is etched to form a deep via hole.

In addition, when the deep via hole is formed, a groove may be formed on the sidewall of a photodiode region adjacent to the insulating layer due to an etch selectivity of the photodiode and the insulating layer. In this case, since the photodiode does not contact the metal plug, photo charges cannot smoothly move, resulting in generation of a dark current and reduction of saturation and sensitivity.

### BRIEF SUMMARY

Embodiments of the present invention provide an image sensor and a method for manufacturing the same, which can improve transmission efficiency of photocharges by forming an ohmic contact layer at an upper part of an image sensing device to facilitate a contact between the ohmic contact layer and an interconnection for a signal output.

In one embodiment, an image sensor can comprise: a semiconductor substrate having a pixel region and a peripheral region defined therein; a readout interconnection on the semiconductor substrate connected to the pixel region; a ground interconnection on the semiconductor substrate connected to the peripheral region; an interlayer dielectric on the semiconductor substrate; a second doped layer, a first doped layer, and an ohmic contact layer stacked on the interlayer dielectric, wherein the first doped layer is on the second doped layer and the ohmic contact layer is on the first doped layer; an image sensing device in the pixel region, wherein the image sensing device comprises the ohmic contact layer, the first doped layer, and a portion of the second doped layer corresponding to the pixel region; a first metal contact extending through the image sensing device and the interlayer dielectric, wherein the first contact is in contact with the readout interconnection; a barrier pattern on a sidewall of the first metal contact; and a second metal contact on the first metal contact and a portion of the ohmic contact layer, wherein the second metal contact has a width greater than a width of the first metal contact, wherein the second metal contact is in contact with the first metal contact and the ohmic contact layer.

In another embodiment, a method for manufacturing an image sensor can comprise: forming a pixel region and a peripheral region in a semiconductor substrate; forming a readout interconnection on the semiconductor substrate connected to the pixel region; forming a ground interconnection on the semiconductor substrate connected to the peripheral region; forming an interlayer dielectric on the semiconductor substrate; bonding an image sensing device to the interlayer dielectric, the image sensing device comprising a second doped layer, a first doped layer, and an ohmic contact layer stacked therein; forming a first via hole through the image sensing device and the interlayer dielectric exposing the readout interconnection; forming a barrier pattern on a sidewall of the first via hole; forming a metal contact in the first via hole; forming a trench over the via hole and having a width greater than a width of the first via hole by removing a portion of the metal contact and a portion of the barrier pattern to expose the ohmic contact layer at sides of the first via hole; and forming a contact plug in the trench.

In yet another embodiment, a method for manufacturing an image sensor can comprise forming a pixel region and a peripheral region in a semiconductor substrate; forming a readout interconnection on the semiconductor substrate connected to the pixel region; forming a ground interconnection on the semiconductor substrate connected to the peripheral region; forming an interlayer dielectric on the semiconductor substrate; forming an image sensing device comprising a second doped layer, a first doped layer, and an ohmic contact layer on the interlayer dielectric; forming a first via hole through the image sensing device and the interlayer dielectric exposing the readout interconnection; forming a barrier pattern on a sidewall of the first via hole; forming a trench over the via hole and having a width greater than a width of the first via hole to expose the ohmic contact layer; and gap-filling a metal layer in the first via hole and the trench to form metal contacts.

The details of one or more embodiments are set forth in the accompanying drawings and the detailed description below. Other features will be apparent to one skilled in the art from the description, the drawings, and the claims.

### BRIEF DESCRIPTION OF THE DRAWINGS

FIGS. 1 through 15 are cross-sectional views illustrating a method for manufacturing an image sensor according to an embodiment of the present invention.

FIG. 16 is a plan view of an image sensor according to an embodiment of the present invention.

### DETAILED DESCRIPTION

Hereinafter, an image sensor and a method for manufacturing the same according to embodiments of the subject invention will be described in detail with reference to the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

Embodiments of the present invention are not limited to a CMOS image sensor. For example, embodiments can be applied to all image sensors that use a photodiode such as a CCD image sensor.

FIG. 15 is a cross-sectional view illustrating an image sensor according to an embodiment of the present invention. Unexplained reference numerals of FIG. 15 will be described with reference to the accompanying drawings illustrating a method for manufacturing the image sensor below.

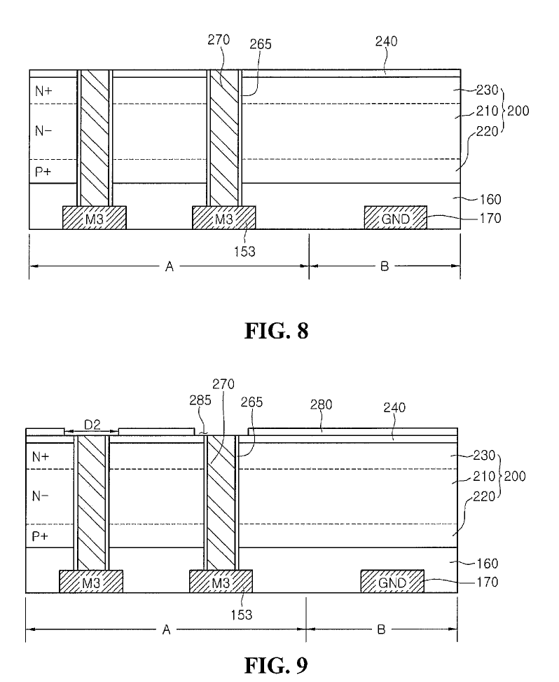

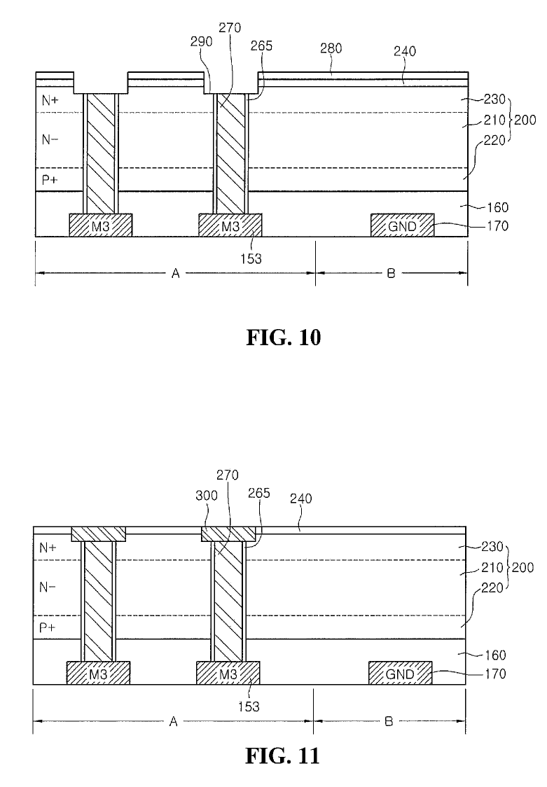

Referring to FIG. 15, in an embodiment, an image sensor can include: a semiconductor substrate 100 (not shown in FIG. 15) having a pixel region A and a peripheral region B defined therein; an interlayer dielectric 160 on the semiconductor substrate 100, the interlayer dielectric 160 comprising a readout interconnection 153 connected to the pixel region A and a ground interconnection 170 connected to peripheral region B; a second doped layer 220, a first doped layer 210, and an ohmic contact layer 230 that are stacked on the interlayer dielectric 160; an image sensing device 200 in the pixel region A, including the ohmic contact layer 230, the first doped layer 210, and at least a portion of the second doped layer 220 (in the peripheral region); a first via hole (250 of FIG. 7) through the image sensing device 200 and the interlayer dielectric 160, the first via hole 250 exposing the readout interconnection 153; a second hard mask 265 on a sidewall of the first via hole 250; a trench (290 of FIG. 10) having a width greater than a width of the first via hole 250 to expose the ohmic contact layer 230 at both sides of the first via hole 250; and a fourth metal contact 270 in the first via hole 250 and the trench 290.

The first doped layer 210 and the ohmic contact layer 230 can be formed of, for example, N-type impurities, and the second doped layer 220 can be formed of, for example, P-type impurities, though embodiments are not limited thereto.

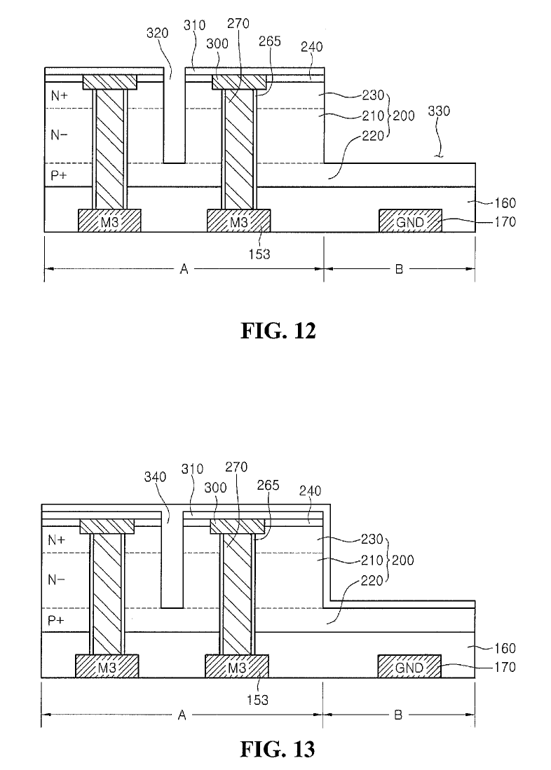

A pixel isolation trench (320 of FIG. 12) can be formed between the fourth metal contacts 270 to separate the image sensing device 200 into pixels. The pixel isolation trench 320 can expose the second doped layer 220. An insulating layer, for example, an oxide and a nitride, can be gap-filled in the pixel isolation trench 320 to form a pixel isolation layer.

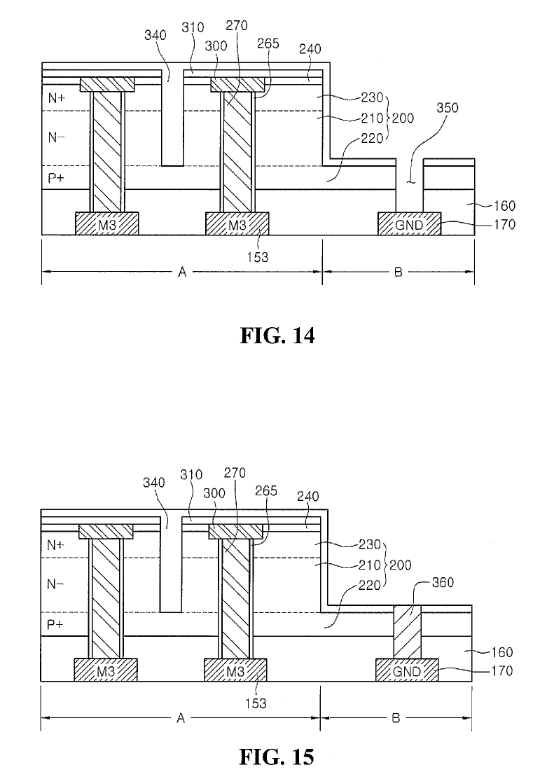

A second via hole (350 of FIG. 14) can be formed through the second doped layer 220 and the interlayer dielectric 160 in the peripheral region B to expose the ground interconnection 170. The ground interconnection 170 and the second doped layer 220 can be exposed through the second via hole 350. A metal material can be gap-filled in the second via hole 350 to form a ground electrode 360. The ground electrode 360 can electrically connect the second doped layer 220 to the ground interconnection 170 to apply a ground voltage to the second doped layer 220 of the image sensing device 200.

The second hard mask 265 can be formed of an insulating layer, for example, an oxide and a nitride, to serve as a barrier pattern of the image sensing device 200. Accordingly, the second doped layer 220 of the image sensing device 200 can be electrically isolated from the fourth metal contact 270.

Hereinafter, a method for manufacturing an image sensor according to an embodiment of the present invention will be described with reference to FIGS. 1 through 15.

Referring to FIG. 1, an interconnection 150 and an interlayer dielectric 160 can be formed on a semiconductor substrate 100 including a readout circuitry 120.

The semiconductor substrate 100 can be, for example a mono- or poly-crystalline silicon substrate, and can be doped with P-type impurities or N-type impurities. In an embodiment, a device isolation layer 110 can be formed in the semiconductor substrate 100 to define an active region. A readout circuit 120 including transistors for a unit pixel can be formed in the active region.

In an embodiment, the readout circuit 120 can include a transfer transistor (Tx) 121, a reset transistor (Rx) 123, a drive transistor (Dx) 125, and a select transistor (Sx) 127. An ion implantation region 130 including a floating diffusion region (FD) 131 and source/drain regions 133, 135, and 137 for each transistor can be formed. The readout circuit 120 can also be applied to a 3 Tr or 5 Tr structure.

In an embodiment, forming the readout circuitry 120 in the semiconductor substrate 100 can include forming an electrical junction region 140 in the first substrate 100 and forming a poly contact 147 connected to the interconnection 150 on the electrical junction region 140.

The electrical junction region 140 can be, for example a P-N junction 140, though embodiments are not limited thereto. For example, the electrical junction region 140 can include a first conductive type ion implantation layer 143 formed on a second conductive type well 141 or a second conductive type epitaxial layer, and a second conductive type ion implantation layer 145 formed on the first conductive type ion implantation layer 143. As shown in FIG. 1, the electrical junction region 140 can be a P0(145)/N−(143)/P−(141) junction, though embodiments are not limited thereto. The semiconductor substrate 100 can be, for example a second conductive type, though embodiments are not limited thereto.

In many embodiments, the device can be designed to provide a potential difference between the source and drain of the transfer transistor (Tx), thereby enabling the full dumping of photocharges. Thus, as photocharges generated in a photodiode are dumped to a floating diffusion region, the sensitivity of an output image can be enhanced.

That is, the electrical junction region 140 can be formed in the first substrate 100 including the readout circuit 120 to provide a potential difference between the source and drain of the transfer transistor (Tx) 121, thereby enabling the full dumping of the photo charges.

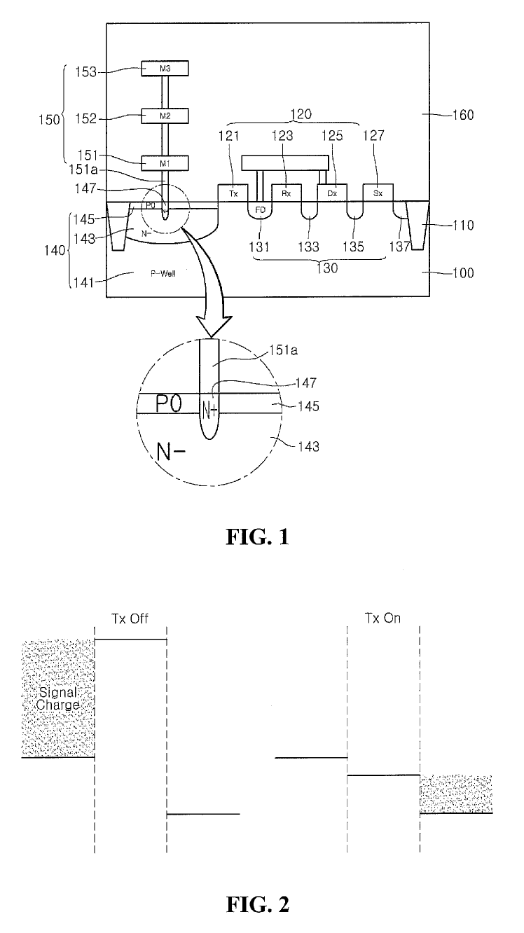

Hereinafter, a dumping structure of photo charges according to an embodiment will be described in detail with reference to FIGS. 1 and 2.

In an embodiment, unlike a second floating diffusion (FD) 131 node of an N+ junction, the P/N/P junction 140 of the electrical junction region 140 can be pinched off at a predetermined voltage without an applied voltage being fully transferred thereto. This voltage is called a pinning voltage. The pinning voltage depends on the P0 (145) and N− (143) doping concentration.

Specifically, electrons generated in the photodiode can be moved to the PNP junction 140 and delivered to the floating diffusion (FD) 131 node to be converted into a voltage when the transfer transistor (Tx) 121 is turned on.

Referring to FIG. 2, due to a potential difference between both ends of the Tx 121, without charge sharing, electrons generated in the photodiode at an upper part of the chip can be fully dumped to the FD 131 node.

Accordingly, unlike a case where a photodiode is simply connected to an N+ junction in a related art image sensor, embodiments of the present invention can inhibit saturation reduction and sensitivity degradation.

The first conductive type connection 147 can be formed between the photodiode and the readout circuit 120 to create a smooth transfer path of photocharges, thereby making it possible to minimize a dark current source and inhibit saturation reduction and sensitivity degradation.

An N+ doping region can be formed as the first conductive type connection 147 for an ohmic contact on the surface of the P0/N−/P− junction 140. The N+ region 147 can be formed to contact N− 143 through the P0 145.

In an embodiment, the width of the first conductive type connection 147 can be minimized to inhibit the first conductive type connection 147 from becoming a leakage source.

Thus, a plug implant can be performed after etching of a first metal contact 151a, though embodiments are not limited thereto. For example, an ion implantation pattern (not shown) can be formed, and then the first conductive type connection 147 can be formed using the ion implantation pattern as an ion implantation mask.

That is, the reason why an N+doping can be locally performed only on a contact formation region as described in the present invention is to minimize a dark signal and facilitate formation of an ohmic contact. If the entire Tx source region is N+ doped like in the related art, a dark signal can increase due to an Si surface dangling bond.

FIG. 3 shows an alternate structure of a readout circuit according to an embodiment of the present invention. Referring to FIG. 3, a first conductive type connection 148 can be formed at one side of the electrical junction region 140.

The N+ connection 148 can be formed at a side of the P0/N−/P− junction 140 for an ohmic contact. In this case, a leakage source may be generated during the formation process of the N+ connection 148 and a M1C contact 151a. This is because an electric field can be generated over the Si surface due to operation while a reverse bias is applied to P0/N−/P− junction 140. A crystal defect generated during the contact formation process inside the electric field may become a leakage source.

Also, when the N+ connection 148 is formed on the surface of P0/N−/P− junction 140, an electric field can be additionally generated due to N+ /P0 junction 148/145. This electric field can also become a leakage source.

Thus, in an embodiment, a layout can be used in which first contact plug 151a can be formed in an active region not doped with a PO layer but including the N+ connection 148 and can be connected to the N-junction 143.

Then, generation of an electric field over the surface of the semiconductor substrate 100 can be inhibited, thereby reducing a dark current of a 3D integrated CIS.

Referring again to FIGS. 1 and 3, an interlayer dielectric 160 and an interconnection 150 can be formed on the semiconductor substrate 100. The interconnection 150 can be formed for each pixel to serve as a readout interconnection that delivers photocharges to the readout circuitry 120.

The interconnection 150 can include, for example a second metal contact 151a, a first metal (M1) 151, a second metal (M2) 152, and a third metal (M3) 153, though embodiments are not limited thereto. In an embodiment, after formation of the third metal 153, an insulating layer can be deposited to cover the third metal 153 and can be planarized to form the interlayer dielectric 160. The surface of the interlayer dielectric 160 can have a uniform surface profile and can be exposed on the semiconductor substrate 100.

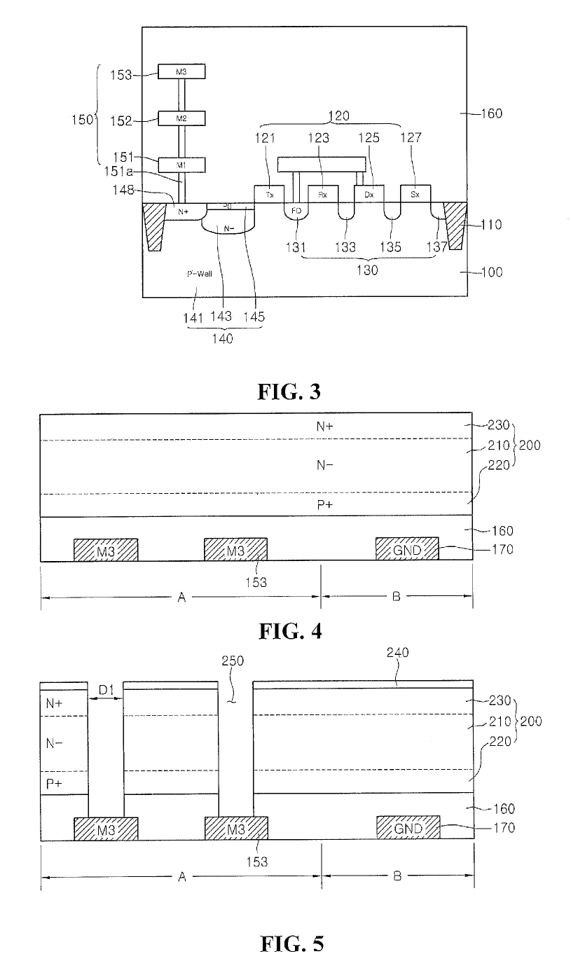

Referring to FIG. 4, an image sensing device 200 can be formed on the interlayer dielectric 160. The image sensing device 200 can include, for example, a PN junction including a first doped layer 210 and a second doped layer 220. An ohmic contact layer 230 can be formed on the first doped layer 210. In an embodiment, the first doped layer 210 can be an N− layer, the second doped layer 220 can be a P+ layer, and the ohmic contact layer 230 can be an N+ layer.

The third metal (M3) 153 of the interconnection 150 and the interlayer dielectric 160 shown in FIG. 4 can represent a portion of the readout interconnection 150 and the interlayer dielectric 160 shown in FIG. 1. For convenience of explanation, portions of the readout circuitry 120 and the interconnection 150 have been omitted in FIG. 4.

The third metal 153 connected to the readout circuitry 120 can be formed in plurality for unit pixels. That is, the third metal 153 and the readout circuitry 120 can be formed in a pixel region A. A ground interconnection GND 170 can be formed to apply a ground voltage to the image sensing device 200. In an embodiment, the ground interconnection GND 170 can be formed simultaneously when the third metal 153 is formed. The ground interconnection 170 can be formed in the peripheral region B to be connected to a logic circuit (not shown).

Hereinafter, a process of forming an image sensing device 200 on the interlayer dielectric 170, according to an embodiment, will be described in detail.

In an embodiment, the first doped layer 210 can be formed by implanting N-type impurities (N−) into a deep region of a P-type carrier substrate (not shown) of a crystalline structure, and the second doped layer 220 can be formed to contact the first doped layer 210 by implanting P-type impurities (P+) into a shallow region of the carrier substrate. Then, the ohmic contact layer 230 can be formed to contact the first doped layer 210 by implanting high-concentration N-type impurities (N+) into a deeper region than that of the first doped layer 210. The ohmic contact layer 230 can reduce a contact resistance between the image sensing device 200 and the interconnection 150.

The first doped layer 210 can be formed to have a broader region (e.g., be thicker) than the second doped layer 220. In this case, a depletion region can be expanded to increase generation of photoelectrons.

Next, a bonding process can be performed to bond the semiconductor substrate 100 and the carrier substrate (not shown) after the second doped layer 220 of the carrier substrate (not shown) is positioned on the interlayer dielectric 160. Then, the carrier substrate can be removed through a heat-treatment or mechanical process to expose the image sensing device 200 bonded to the interlayer dielectric 160. Accordingly, the image sensing device 200 in which the second doped layer 220, the first doped layer 210, and the ohmic contact layer 230 are stacked can be formed on the interlayer dielectric 160.

As described above, the image sensing device 200 can be formed over the readout circuitry 120, thereby increasing a fill factor. Also, since the image sensing device 200 can be bonded on the interlayer dielectric 160 having a uniform surface profile, a physical bonding strength can be improved.

Furthermore, since the semiconductor substrate 100 in which the readout circuitry 120 is formed can be bonded to the image sensing device 200 through a wafer-to-wafer bonding, generation of a defect of the image sensing device 200 can be inhibited.

Referring to FIG. 5, a first via hole 250 can be formed through the image sensing device 200 and the interlayer dielectric 160. The first via hole 250 can expose the third metal 153. For example, the first via hole 250 can have a diameter of a first width DE Also, as seen in FIG. 5, a first via hole 250 can be formed in each unit pixel.

In order to form the first via hole 250, a first hard mask layer (not shown) can be formed along the surface of the image sensing device 200. Then, the first hard mask layer can be patterned to form a first hard mask 240 exposing a portion of the surface of the image sensing device 200 corresponding to the third metal 153 (that is, at least a portion of the image sensing device 200 that is over the third metal 153). The first hard mask 240 can be formed of, for example, an insulating layer such as an oxide and/or a nitride. The image sensing device 200 and the interlayer dielectric 160 can be etched using the first hard mask 240 as an etch mask to form the first via hole 250.

The sidewall of the first via hole 250 can expose the first and second doped layers 210 and 220 and the ohmic contact layer 230 of the image sensing device 200, and the bottom surface of the first via hole 250 can expose the third metal 153.

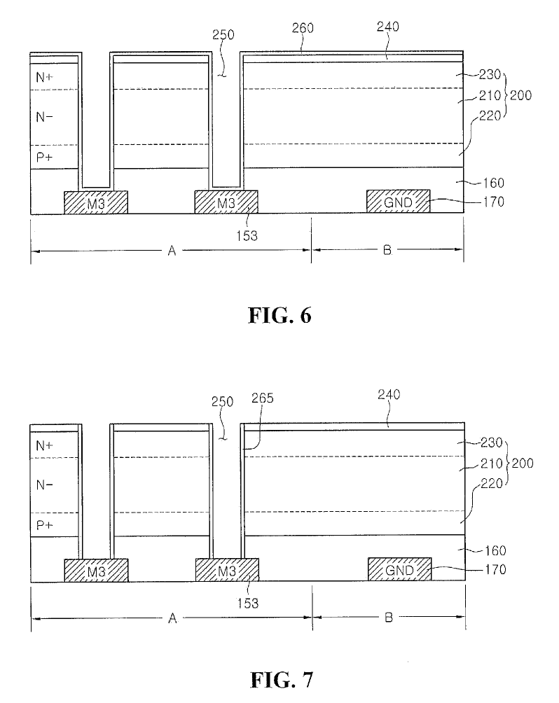

Referring to FIG. 6, a second hard mask layer 260 can be formed along the surface of the first via hole 250 (including on the sidewalls and on the bottom surface of the first via hole 250) and the first hard mask 240. The second hard mask layer 260 can be formed of, for example, the same material as the first hard mask 240.

The second hard mask layer 260 can be formed on the surface of the first hard mask 240, and the sidewall and the bottom surface of the first via hole 250.

The surfaces of the first and second doped layers 210 and 220, the ohmic contact layer 230, and the third metal 153 exposed in the first via hole 250 can be covered by the second hard mask layer 260. The second hard mask layer 260 can be stacked on the first hard mask 240 in the peripheral region B. That is, the second hard mask layer 260 can serve as a barrier layer.

Referring to FIG. 7, a second hard mask 265 can be formed on the sidewall of the first via hole 250. The second hard mask 265 can be formed by performing a blanket etch process on the second hard mask layer 260.

In an embodiment, through the blanket etch process on the second hard mask layer 260, only portions of the second hard mask layer 260 on the surface of the first hard mask 240 and the bottom surface of the first via hole 250 may be etched to expose the surface of the third metal 153, forming the second hard mask 265 only on the sidewall of the first via hole 250.

The upper surface of the image sensing device 200 can be covered by the first hard mask 240. The image sensing device 200 along the sidewall of the first via hole 250 can be covered by the second hard mask 265.

Referring to FIG. 8, a fourth metal contact 270 can be formed in the first via hole 250. The fourth metal contact 270 can be electrically connected to the third metal 153. In an embodiment, the fourth metal contact 270 can be in physical contact with the third metal 153. Also, if a first via hole 250 is formed in each unit pixel, a fourth metal contact 270 can be formed in each via hole 250 (that is, in each unit pixel).

The fourth metal contact 270 can be formed, for example, through a gap-fill of a metal material in the first via hole 250. The fourth metal contact 270 can be formed of any suitable material known in the art, for example, at least one of W, Al, Ti, Ta/Ti, TiN, Ti/TiN, and Cu. In an embodiment, the uppermost surface of the fourth metal contact 270 can have the same height as that of the first hard mask 240.

The fourth metal contact 270 can be formed in the first via hole 250 to be electrically connected to the readout circuitry 120 through the third metal 153.

The second hard mask 265 can be present on the sidewall of the fourth metal contact 270. Accordingly, the fourth metal contact 270 can be electrically isolated from the image sensing device 200. That is, the second hard mask 265 can serve as a barrier pattern of the fourth metal contact 270 such that the fourth metal contact 270 can be electrically isolated from the second doped layer 220.

Referring to FIG. 9, a third mask 280 having an opening 285 exposing the upper surface of the fourth metal contact 270 can be formed on the first hard mask 240. For example, the third hard mask 280 can be formed of an insulating layer such as an oxide and/or a nitride.

The opening 285 of the third hard mask 280 can be formed to have a second width D2 greater than the first width D1 of the first via hole 250. Accordingly, a portion of the first hard mask 240 over a portion of the image sensing device 200 at both sides of the first via hole 250 can be exposed by the opening 285.

Referring to FIG. 10, a trench 290 can be formed to expose the ohmic contact layer 230 of the image sensing device 200. The trench 290 can be formed by selectively etching the first hard mask 240, the ohmic contact layer 230, the second hard mask 265, and the fourth metal contact 270 using the third hard mask 280 as an etch mask. When the trench 290 is formed, process conditions such as etching duration, etching gases, or chemicals can be adjusted to stop the etching process upon exposure of the ohmic contact layer 230.

The trench 290 can be formed to have the same width as the opening 285 that is greater than the diameter of the first via hole 250. Accordingly, the ohmic contact layer 230 can be exposed by the sidewall of the trench 290. Also, the ohmic contact layer 230 and the fourth metal contact 270 can be exposed at the bottom surface of the trench 290.

Referring to FIG. 11, a contact plug 300 can be formed in the trench 290. The contact plug 300 can electrically connect the ohmic contact layer 230 to the fourth metal contact 270.

The contact plug 300 can be formed through, for example, a planarization process after a gap-fill of a metal material in the trench 290. In an embodiment, the uppermost surface of the contact plug 300 can have the same height as that of the first hard mask 240. The contact plug 300 can be formed of, for example, the same material as the fourth metal contact 270.

The contact plug 300 can be formed in the trench 290 to electrically connect the ohmic contact layer 230 to the third metal 153. That is, the image sensing device 200 can be electrically connected to the readout circuitry 120 through the contact plug 300, the fourth metal contact 270, and the interconnection 150 (including the third metal 153).

Accordingly, photocharges generated in the image sensing device 200 can be delivered to the readout circuitry 120 through the contact plug 300, the fourth metal contact 270, and the interconnection 150. In this case, since the first and second doped layers 220 of the image sensing device 200 are electrically isolated from the fourth metal contact 270 through the second hard mask 265, the photocharges generated in the image sensing device 200 can be delivered to the readout circuitry 120 only through the contact plug 300 and the fourth metal contact 270.

As described above, the ohmic contact layer 230 can be formed at an upper part of the image sensing device 200, facilitating electrical contact with the fourth metal contact 270 and the contact plug 300 for transmission of photocharges. That is, the fourth metal contact 270 can be formed in the first via hole 250 through the image sensing device 200, and the second hard mask 265 can be formed between the first via hole 250 and the fourth metal contact 270 (that is, on the sidewall(s) of the first via hole 250). Accordingly, the fourth metal contact 270 can be electrically connected to the third metal 153. Since the ohmic contact layer 230 can be formed at an upper part of the image sensing device 200, a process for forming the trench 290 to form the contact plug 300 can be facilitated. Also, since the contact plug 300 can be formed through a gap-fill of a metal material in the trench 290 having a shallow depth and a relatively large width, the electrical contact between the contact plug 300 and the fourth metal contact 270 can be effectively achieved.

Although it has been described that the trench 290 is formed after the formation of the fourth metal contact 270, in an alternative embodiment, the trench 290 can be formed after the formation of the first via hole 250 and before formation of the fourth metal contact 270. Although not shown, the fourth metal contact 270 can be formed by gap-filling a metal layer in the first via hole 250 and the trench 290 after the trench 290 exposing the ohmic contact layer 230 at both sides of the first via hole 250 is formed.

Referring to FIG. 12, a pixel isolation trench 320 can be formed in the image sensing device 200 to separate the image sensing device 200 into unit pixels. Also, a portion of the ohmic contact layer 230 and a portion of the first doped layer 210 of the image sensing device 200 corresponding to the peripheral region B can be removed to form an exposure part 330. In an embodiment, the portion of the ohmic contact layer 230 and the portion of the first doped layer 210 of the image sensing device 200 corresponding to the peripheral region B can be removed when the pixel isolation trench 320 is formed.

The first hard mask 240, the ohmic contact layer 230, and the first doped layer can be selectively etched to form the pixel isolation trench 320 and the exposure part 330. The second doped layer 220 can be exposed by the pixel isolation trench 320 and the exposure part 330.

The pixel isolation trench 320 and the exposure part 330 can be formed through an etching process using a fourth hard mask 310 on the first hard mask 240. The fourth hard mask 310 can selectively expose a portion of the surface of the first hard mask 240 between adjacent contact plugs 300. The fourth hard mask 310 can also expose the portion of the first hard mask 240 corresponding to the peripheral region B.

In an embodiment, the first hard mask 240, the ohmic contact layer 230, and the first doped layer 210 can be etched using the fourth hard mask 310 as an etch mask to form the pixel isolation trench 320 in the pixel region A and the exposure part 330 in the peripheral region B.

The pixel isolation trench 320 can separate the image sensing device 200 of the pixel region A into unit pixels. The exposure part 330 can expose the second doped layer 220 corresponding to the peripheral region B.

Thus, the second doped layer 220 can extend from the pixel region A to the peripheral region B.

Referring to FIG. 13, a pixel isolation layer 340 can be formed in the pixel isolation trench 320 and on the exposure part 330. In an embodiment, the pixel isolation layer 340 can be formed to gap-fill the pixel isolation trench 320. The pixel isolation layer 340 can be formed along the surface of the exposure part 330 to cover the sidewall of the image sensing device 200 in the pixel region A and the surface of the second doped layer 220 in the peripheral region 340. The pixel isolation layer 340 can be formed of an insulating material such as an oxide and/or a nitride.

The pixel isolation layer 340 can separate the image sensing device 200 of the pixel region A into unit pixels. Also, the image sensing device 200 and the second doped layer 220 of the peripheral region B exposed by the exposure part 330 can be protected by the pixel isolation layer 340.

Since the second doped layer 220 can remain in the pixel region A and the peripheral region B, the pixel region A and the peripheral region B can be electrically connected by the second doped layer 220. Though the pixel region A can be electrically connected by the second doped layer 220, photocharges generated in the image sensing device 200 cannot move through the P+ layer, the second doped layer 220. Accordingly, the image sensing device 220 can be separated into unit pixels.

Referring to FIG. 14, a second via hole 350 can be formed through the pixel isolation layer 340, the second doped layer 220 and the interlayer dielectric 160 of the peripheral region B to expose the ground interconnection 170. In an embodiment, to form the second via hole 350, a mask pattern (not shown) can be formed to expose the pixel isolation layer 340 corresponding to the ground interconnection 170. Then, the pixel isolation layer 340, the first doped layer 210, and the interlayer dielectric 160 can be etched using the mask pattern (not shown) as an etch mask to form the second via hole 350.

Accordingly, the second doped layer 220 can be exposed along the sidewall of the second via hole 350, and the ground interconnection 170 can be exposed on the bottom surface of the second via hole 350.

Referring to FIG. 15, a ground electrode 360 can be formed in the second via hole 350. The ground electrode 360 can be electrically connected to the ground interconnection 170 and the second doped layer 220. That is, the ground electrode 360 can serve as a ground contact of the image sensing device 200. In an embodiment, the ground electrode 360 can be in physical contact with the ground interconnection 170 and the second doped layer 220.

A metal material can be filled in the second via hole 350 to form the ground electrode 360. The ground electrode 360 can be formed of any suitable material known in the art, for example, at least one of W, Al, Ti, Ta/Ti, TiN, Ti/TiN, and Cu.

Since the ground electrode 360 can be formed in the second via hole 350 formed through the second doped layer 220 of the peripheral region B, the ground interconnection 170 and the second doped layer 220 can be electrically connected.

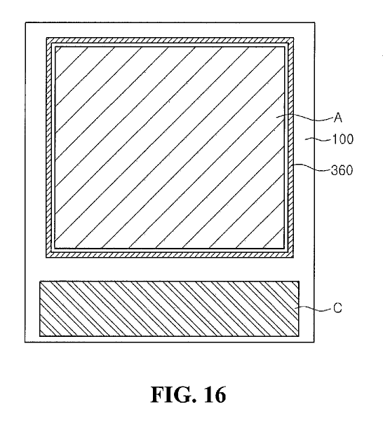

Referring to FIG. 16, the ground electrode 360 can be formed to surround the pixel region A. Although not shown, a portion of the ground electrode 360 can be electrically connected to the second doped layer 220 of the pixel region A, thereby applying a ground voltage to the whole image sensing device 200 of the pixel region A. The reference symbol C can be, for example, a logic circuit.

In an alternative embodiment, the ground electrode 360 can be formed only at one side of the pixel region A to be electrically connected to the second doped layer 220.

As described above, the second doped layer 220 formed at a bottom portion of the image sensing device 200 can be electrically connected to the ground electrode 360 to connect the ground voltage to the image sensing device 200. Accordingly, a process for forming an upper electrode of the image sensing device 200 can be omitted to simplify the overall process. Also, since a separate electrode need not to be formed on the image sensing device 200, the fill factor of the image sensing device 200 can be enhanced.

Although not shown, a color filter and a microlens can be formed over the image sensing device 200.

According to embodiments of the present invention, an image sensing device can be formed on a semiconductor substrate in which a readout circuitry is formed, thereby enhancing the fill factor.

Also, an ohmic contact layer (such as an N+ layer) can be positioned at an upper part of the image sensing device, and formation of a contact plug for delivering photocharges generated in the image sensing device to the readout circuitry can be facilitated. That is, after forming a fourth metal contact connected to the readout circuitry through the image sensing device, a trench can be formed to expose an upper region of the fourth metal contact and the ohmic contact layer. Then, a metal material can be gap-filled in the trench to facilitate electrical connection between the fourth metal contact and the ohmic contact layer of the image sensing device.

In addition, a second doped layer of the image sensing device can be formed extending from a pixel region to a peripheral region, and a ground electrode of the peripheral region and the second doped layer can be electrically connected, thereby increasing a light-receiving area of the image sensing device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate having a pixel region and a peripheral region defined therein;
a readout interconnection on the semiconductor substrate connected to the pixel region;
a ground interconnection on the semiconductor substrate connected to the peripheral region;
an interlayer dielectric on the semiconductor substrate;
a second doped layer, a first doped layer, and an ohmic contact layer stacked on the interlayer dielectric, wherein the first doped layer is on the second doped layer and the ohmic contact layer is on the first doped layer;
an image sensing device in the pixel region, wherein the image sensing device comprises the ohmic contact layer, the first doped layer, and a portion of the second doped layer corresponding to the pixel region;
a first metal contact extending through the image sensing device and the interlayer dielectric, wherein the first contact is in contact with the readout interconnection;
a barrier pattern on a sidewall of the first metal contact; and
a second metal contact on the first metal contact and a portion of the ohmic contact layer, wherein the second metal contact has a width greater than a width of the first metal contact, wherein the second metal contact is in contact with the first metal contact and the ohmic contact layer.

2. The image sensor according to claim 1, further comprising a pixel isolation layer between the first metal contact and an adjacent first metal contact, the pixel isolation layer separating the image sensing device into pixels.

3. The image sensor according to claim 2, wherein the pixel isolation layer extends through the ohmic contact layer and the first doped layer and is in contact with the second doped layer.

4. The image sensor according to claim 2, further comprising:
a ground electrode extending through the second doped layer and the interlayer dielectric of the peripheral region, wherein the ground electrode is in contact with the ground interconnection.

5. The image sensor according to claim 1, wherein the barrier pattern comprises an oxide and a nitride.

6. The image sensor according to claim 1, wherein the first doped layer and the ohmic contact layer each comprise N-type impurities, and wherein the second doped layer comprises P-type impurities.

7. The image sensor according to claim 1, wherein the first doped layer is an N− layer, and wherein the ohmic contact layer is an N+ layer, and wherein the second doped layer is a P+ layer.

8. A method for manufacturing an image sensor, comprising:
forming a pixel region and a peripheral region in a semiconductor substrate;
forming a readout interconnection on the semiconductor substrate connected to the pixel region;
forming a ground interconnection on the semiconductor substrate connected to the peripheral region;
forming an interlayer dielectric on the semiconductor substrate;
bonding an image sensing device to the interlayer dielectric, the image sensing device comprising a second doped layer, a first doped layer, and an ohmic contact layer stacked therein;
forming a first via hole through the image sensing device and the interlayer dielectric exposing the readout interconnection;
forming a barrier pattern on a sidewall of the first via hole;
forming a metal contact in the first via hole;
forming a trench over the via hole and having a width greater than a width of the first via hole by removing a portion of the metal contact and a portion of the barrier pattern to expose the ohmic contact layer at sides of the first via hole; and
forming a contact plug in the trench.

9. The method according to claim 8, further comprising:
forming a pixel isolation trench through the ohmic contact layer and the first doped layer between the metal contact and an adjacent metal contact to separate the image sensing device into pixels, wherein the pixel isolation trench exposes the second doped layer; and
forming a pixel isolation layer in the pixel isolation trench.

10. The method according to claim 9, further comprising removing a portion of the ohmic contact layer and a portion of the first doped layer corresponding to the peripheral region to expose the second doped layer in the peripheral region, including a portion of the second doped layer corresponding to the ground interconnection.

11. The method according to claim 10, wherein the exposure of the second doped layer in the peripheral region and the forming of the pixel isolation trench are simultaneously performed.

12. The method according to claim 10, further comprising:
etching the second doped layer and the interlayer dielectric of the peripheral region to form a second via hole, the second via hole exposing the ground interconnection; and
forming a ground electrode in the second via hole.

13. The method according to claim 8, wherein forming the barrier pattern on the sidewall on the first via hole comprises:
forming a barrier layer on the image sensing device, including on the sidewall of the first via hole and on the readout interconnection; and
performing a blanket etch process on the barrier layer to remove the barrier layer from an uppermost surface of the image sensing device and from the readout interconnection.

14. The method according to claim 8, wherein forming the trench comprises:
forming a hard mask on the image sensing device exposing the metal contact; wherein the hard mask has an opening with a width greater than that of the first via hole; and
selectively removing a portion the metal contact, a portion of the barrier pattern, and a portion of the ohmic contact layer using the hard mask as an etch mask.

15. The method according to claim 8, wherein the first doped layer and the ohmic contact layer each comprise N-type impurities, and wherein the second doped layer comprises P-type impurities.

16. The method according to claim 8, wherein the first doped layer is an N- layer, and wherein the ohmic contact layer is an N+ layer, and wherein the second doped layer is a P+ layer.

17. A method for manufacturing an image sensor, comprising:
forming a pixel region and a peripheral region in a semiconductor substrate;
forming a readout interconnection on the semiconductor substrate connected to the pixel region;
forming a ground interconnection on the semiconductor substrate connected to the peripheral region;
forming an interlayer dielectric on the semiconductor substrate;
forming an image sensing device comprising a second doped layer, a first doped layer, and an ohmic contact layer on the interlayer dielectric;
forming a first via hole through the image sensing device and the interlayer dielectric exposing the readout interconnection;
forming a barrier pattern on a sidewall of the first via hole;
forming a trench over the via hole and having a width greater than a width of the first via hole to expose the ohmic contact layer; and
gap-filling a metal layer in the first via hole and the trench to form metal contacts.

18. The method according to claim 17, further comprising:
forming a pixel isolation trench through the ohmic contact layer and the first doped layer between the metal contacts and an adjacent set of metal contacts to separate the image sensing device into pixels, wherein the pixel isolation trench exposes the second doped layer; and
forming a pixel isolation layer in the pixel isolation trench.

19. The method according to claim 18, further comprising removing a portion of the ohmic contact layer and a portion of the first doped layer corresponding to the peripheral region to expose the second doped layer in the peripheral region, including a portion of the second doped layer corresponding to the ground interconnection.

20. The method according to claim 17, wherein the first doped layer is an N− layer, and wherein the ohmic contact layer is an N+ layer, and wherein the second doped layer is a P+ layer.
